(19) United States
(12) Patent Application Publication
(10) Pub. No.: US 2024/0306344 A1
(43) Pub. Date: Sep. 12, 2024

(54) System and Method for in-Row Air-to-Liquid Cooling Systems

(71) Applicant: Hoffman Enclosures Inc., Anoka, MN (US)

(72) Inventors: Dietmar Mann, Remchingen (DE); Stefan Djuranec, Birkenfeld (DE); Jochen Müller, Engelsbrand (DE)

(21) Appl. No.: 18/598,691

(22) Filed: Mar. 7, 2024

Related U.S. Application Data
(60) Provisional application No. 63/488,853, filed on Mar. 7, 2023.

(51) Int. Cl. H05K 7/20

(52) U.S. Cl. CPC H05K 7/20263; H05K 7/20209; H05K 7/20781

(57) ABSTRACT

An air-to-liquid cooling system includes a cabinet, a fluid inlet, a fluid outlet, a heat exchanger within the cabinet, a plurality of fan assemblies, and a hot-swappable control module. The cabinet defines a front and rear portion, and includes lateral side panels and a front face. The heat exchanger is in fluid communication with the fluid inlet and fluid outlet. The heat exchanger is positioned at an oblique angle relative to the lateral side panels of the cabinet. The plurality of fan assemblies are mounted along the front face and further include a fan and blind mate connectors. The hot-swappable control module is positioned vertically above the plurality of fan assemblies. The hot-swappable control module includes a controller that is in electronic communication with the plurality of fan assemblies, and includes instructions stored within the controller to control a speed of the fans.

### CROSS-REFERENCE TO RELATED APPLICATIONS

This application claims priority to U.S. Provisional Patent Application No. 63/488,853 filed Mar. 7, 2023, the entirety of which is incorporated by reference.

### BACKGROUND

Several trends in the electronics industry have combined to increase the importance of thermal management, including heat removal for electronic components. In particular, the need for faster and more densely packed circuits has had a direct impact on the importance of thermal management. For example, power dissipation and heat production increase as device operating frequencies increase. Also, increased operating frequencies may be possible at lower device junction temperatures. Further, as more and more components are packed onto a single chip or module, heat flux increases, resulting in the need to remove more power from a given size chip or module. These trends have combined to create applications and environments where it is no longer desirable to remove heat solely by traditional air-cooling methods. Such air-cooling techniques are inherently limited in their ability to extract heat from electronic components with moderate to high power density.

Modem computing workloads, data generation, and data consumption have increased demand for computing capacity. To address these needs, data centers house electrical computing systems which can include hardware for networking, computing, and storage for example, and can host workloads and store data. In operation, these electrical components generate considerable heat, which can degrade the performance of computing systems and lead to overheating. To address the inefficiencies caused by overheating, cooling systems are provided for data centers to transfer heat away from electrical components, increasing the lifetime and productivity of the electrical system. In some cases, cooling systems for data centers can include multiple coolant circuits, wherein heat from a circuit proximate the electrical components is rejected to another coolant circuit.

### SUMMARY

Embodiments of the disclosure include an air-to-liquid cooling system including a cabinet, a fluid inlet, a fluid outlet, a heat exchanger within the cabinet, a plurality of fan assemblies, and a hot-swappable control module. The cabinet defines a front and rear portion and includes lateral side panels and a front face. The heat exchanger is in fluid communication with the fluid inlet and fluid outlet. The heat exchanger is also positioned at an oblique angle relative to the lateral side panels of the cabinet. The plurality of fan assemblies are mounted along the front face and further include a fan and blind mate connectors. Correspondingly, the cabinet also includes blind mate connectors that are configured to interface with the blind mate connectors of the fan assemblies. The hot-swappable control module is positioned vertically above the plurality of fan assemblies. The hot-swappable control modules include a controller that is in electronic communication with the plurality of fan assemblies, and includes instructions stored within the controller to control a speed of the fans.

In some embodiments, an air-to-liquid cooling system can further comprise a plurality of hot-swappable power supply units mounted along the front face. In other embodiments, the plurality of hot-swappable power supply units includes three hot-swappable control units. In other embodiments, the plurality of power supply units provide an N+1 redundancy of power supply units for the air-to-liquid cooling system. In other embodiments, an axis is defined transverse to the front face, wherein each of the plurality of fan assemblies, the hot-swappable power supply units, and the hot-swappable controller are removable from the cabinet in a direction parallel to the axis. In some embodiments, the air-to-liquid cooling system further includes a valve positioned downstream of the fluid inlet and upstream of the heat exchanger, where the valve movable between a fully open position and a fully closed position. Further, when the valve is in a fully-closed position, a fluid connection between the heat exchanger and the fluid inlet is interrupted. In other embodiments, when the valve is in the fully closed position, the fluid inlet is in direct fluid communication with the fluid outlet. In other embodiments, when a communication between the controller and the plurality of fan assemblies is interrupted, the fans of the fan assemblies continue to rotate at a default speed. In some embodiments, the air-to-liquid cooling system includes vents, where the vents are defined in the lateral side panels. In some embodiments, the air-to-liquid cooling system further comprises a plurality of electrical inlets, where the fluid inlet, the fluid outlet, and the plurality of electrical inlets are provided in the rear portion of the cabinet. In some embodiments, the cabinet of the air-to-liquid cooling system defines a width of about 600 mm. In some embodiments, the hot-swappable control module is one of a plurality of hot-swappable control modules, and each hot-swappable control module of the plurality of hot-swappable control modules is mounted along the front face.

Other embodiments of the disclosure include a cabinet, which defines a front portion and a rear portion. The cabinet further includes lateral side panels and a front face. The air-to-liquid cooling system also includes a fluid inlet, a fluid outlet, a fluid flow path, a heat exchanger a bypass valve, and a hot-swappable control module. The flow path is defined between the fluid inlet and the fluid outlet. The bypass valve is configured to move between a fully open position and a fully closed position. In the fully open position, the heat exchanger is positioned fluidly along the fluid flow path. In the fully closed position, the heat exchanger is not positioned fluidly along the fluid flow path. The hot-swappable control module is mounted within the front portion of the cabinet. The hot-swappable control module includes blind mate connectors and a controller. The controller is in electrical communication with the bypass valve. The controller has instructions stored within the controller to control a position of the bypass valve.

In some embodiments, both the fluid inlet and fluid outlet comprise a quick-disconnect fitting. In other embodiments, the air-to-liquid cooling system further comprises a plurality of power supply units mounted at the front portion and a plurality of fan assemblies mounted at the front portion. In other embodiments, the each of the plurality of power supply units and the plurality of fan assemblies include blind mate connections. In other embodiments, an axis extends through the front portion and rear portion, where each of the hot-swappable control module, the plurality of power supply units, and the fan assemblies are configured to be inserted into the front portion in a direction parallel the axis. In other embodiments, each of the hot-swappable control module, the plurality of power supply units, and the fan assemblies are configured for toolless removal from the cabinet.

Other embodiments of the disclosure include a method of providing a cooling system within a data center. The method includes providing a cabinet defining a front portion and a rear portion, inserting, in a first direction, a hot-swappable fan assembly into the front portion, inserting in the first direction, a hot-swappable control module into the front portion, inserting, in the first direction, a power supply unit into the front portion, providing, at the fluid inlet, a fluid coolant, sensing, at a first sensor, a parameter of the fluid coolant, providing the parameter to the controller, and based on the parameter, generating, at the controller, a speed signal for the fan of the hot-swappable fan assembly the speed signal being generated based on the fan speed PID control. A heat exchanger, a fluid inlet, and a fluid outlet are installed within the cabinet. The hot-swappable fan assembly includes a fan. The hot-swappable control module includes a controller that has instructions thereon for implementing a fan speed PID control for controlling a speed of the fan.

### BRIEF DESCRIPTION OF THE DRAWINGS

The accompanying drawings, which are incorporated in and form a part of this specification, illustrate embodiments of the disclosure and, together with the description, serve to explain the principles of embodiments of the disclosure:

FIG. 1 is a schematic of an in-row air-to-liquid cooling system, according to an embodiment of the present disclosure;

FIG. 2 is an isometric view of an in-row air-to-liquid cooling unit, according to an embodiment of the present disclosure;

FIG. 3 is an isometric view of the in-row air-to-liquid cooling unit of FIG. 1 further including a door mounted at a front of the air-to-liquid cooling unit, according to an embodiment of the disclosure;

FIG. 4 is a front elevation view of the in-row air-to-liquid cooling unit of FIG. 3 including a front door with a touch-screen panel;

FIG. 5 is a front elevation view of the in-row air-to-liquid cooling unit of FIG. 2;

FIG. 6 is a rear elevation view of the in-row air-to-liquid cooling unit of FIG. 2, including a rear door;

FIG. 7 is a rear elevation view of the in-row air-to-liquid cooling unit of FIG. 2;

FIG. 8 is a top plan section view of the in-row air-to-liquid cooling unit of FIG. 2, showing the air-to-liquid heat exchanger within the unit at an oblique angle relative to lateral side panels of the unit;

FIG. 9 is a partial view of components of the in-row air-to-liquid cooling unit of FIG. 2, illustrating plumbing elements of the unit;

FIG. 10 is a partial view of components of another embodiment of an in-row air-to-liquid cooling unit, illustrating plumbing elements of the unit;

FIG. 11 is an isometric view of an electrical enclosure for use with the in-row air-to-liquid cooling unit of FIG. 2 according to embodiments;

FIG. 12 is an isometric view of a control module for the in-row air-to-liquid cooling unit of FIG. 2, according to an embodiment;

FIGS. 13A and 13B are isometric views of fan assemblies used in the in-row air-to-liquid cooling unit of FIG. 2;

FIG. 14 is a system schematic of an in-row air-to-liquid cooling units, according to some embodiments;

FIGS. 15 and 16 are schematics for feedback control systems for in-row air-to-liquid cooling systems;

FIGS. 17A-17E are system schematics showing a controller, and an interface board for controlling elements of a high-density in-row air-to-liquid cooling system;

FIG. 18 is an isometric view of a control module for in-row cooling units, according to some aspects of the disclosure.

### DETAILED DESCRIPTION

Before any embodiments of the present disclosure are explained in detail, it is to be understood that the disclosure is not limited in its application to the details of construction and the arrangement of components set forth in the following description or illustrated in the following drawings. The disclosed systems and methods are capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

Also as used herein, unless otherwise limited or defined, “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as “either,” “one of,” “only one of,” or “exactly one of” For example, a list of “one of A, B, or C” indicates options of: A, but not B and C; B, but not A and C; and C, but not A and B. A list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more of A, one or more of B, and one or more of C. Similarly, a list preceded by “a plurality of” (and variations thereon) and including “or” to separate listed elements indicates options of multiple instances of any or all of the listed elements. For example, the phrases “a plurality of A, B, or C” and “two or more of A, B, or C” indicate options of: A and B; B and C; A and C; and A, B, and C.

In some implementations, devices or systems disclosed herein can be utilized, manufactured, installed, etc. using methods embodying aspects of the disclosed systems and methods. Correspondingly, any description herein of particular features, capabilities, or intended purposes of a device or system is generally intended to include disclosure of a method of using such devices for the intended purposes, of a method of otherwise implementing such capabilities, of a method of manufacturing relevant components of such a device or system (or the device or system as a whole), and of a method of installing disclosed (or otherwise known) components to support such purposes or capabilities. Similarly, unless otherwise indicated or limited, discussion herein of any method of manufacturing or using for a particular device or system, including installing the device or system, is intended to inherently include disclosure, as embodiments of the present disclosure, of the utilized features and implemented capabilities of such device or system.

In some embodiments, aspects of the disclosure, including computerized implementations of methods according to the disclosure, can be implemented as a system, method, apparatus, or article of manufacture using standard programming or engineering techniques to produce software, firmware, hardware, or any combination thereof to control a processor device (e.g., a serial or parallel general purpose or specialized processor chip, a single- or multi-core chip, a microprocessor, a field programmable gate array, any variety of combinations of a control module, arithmetic logic unit, and processor register, and so on), a computer (e.g., a processor device operatively coupled to a memory), or another electronically operated controller to implement aspects detailed herein. Accordingly, for example, embodiments of the disclosure can be implemented as a set of instructions, tangibly embodied on a non-transitory computer-readable media, such that a processor device can implement the instructions based upon reading the instructions from the computer-readable media. Some embodiments of the disclosure can include (or utilize) a control device such as an automation device, a special purpose or general purpose computer including various computer hardware, software, firmware, and so on, consistent with the discussion below. As specific examples, a control device can include a processor, a microcontroller, a field-programmable gate array, a programmable logic controller, logic gates etc., and other typical components that are known in the art for implementation of appropriate functionality (e.g., memory, communication systems, power sources, user interfaces and other inputs, etc.). In some embodiments, a control device can include a centralized hub controller that receives, processes and (re)transmits control signals and other data to and from other distributed control devices (e.g., an engine controller, an implement controller, a drive controller, etc.), including as part of a hub-and-spoke architecture or otherwise.

The term “article of manufacture” as used herein is intended to encompass a computer program accessible from any computer-readable device, carrier (e.g., non-transitory signals), or media (e.g., non-transitory media). For example, computer-readable media can include but are not limited to magnetic storage devices (e.g., hard disk, floppy disk, magnetic strips, and so on), optical disks (e.g., compact disk (CD), digital versatile disk (DVD), and so on), smart cards, and flash memory devices (e.g., card, stick, and so on). Additionally it should be appreciated that a carrier wave can be employed to carry computer-readable electronic data such as those used in transmitting and receiving electronic mail or in accessing a network such as the Internet or a local area network (LAN). Those skilled in the art will recognize that many modifications may be made to these configurations without departing from the scope or spirit of the claimed subject matter.

Certain operations of methods according to the disclosure, or of systems executing those methods, may be represented schematically in the FIGS. or otherwise discussed herein. Unless otherwise specified or limited, representation in the FIGS. of particular operations in particular spatial order may not necessarily require those operations to be executed in a particular sequence corresponding to the particular spatial order. Correspondingly, certain operations represented in the FIGS., or otherwise disclosed herein, can be executed in different orders than are expressly illustrated or described, as appropriate for particular embodiments of the disclosure. Further, in some embodiments, certain operations can be executed in parallel, including by dedicated parallel processing devices, or separate computing devices configured to interoperate as part of a large system.

As used herein in the context of computer implementation, unless otherwise specified or limited, the terms “component,” “system,” “module,” “block,” and the like are intended to encompass part or all of computer-related systems that include hardware, software, a combination of hardware and software, or software in execution. For example, a component may be, but is not limited to being, a processor device, a process being executed (or executable) by a processor device, an object, an executable, a thread of execution, a computer program, or a computer. By way of illustration, both an application running on a computer and the computer can be a component. One or more components (or system, module, and so on) may reside within a process or thread of execution, may be localized on one computer, may be distributed between two or more computers or other processor devices, or may be included within another component (or system, module, and so on).

Also as used herein, unless otherwise limited or defined, the terms “about,” “substantially,” and “approximately” refer to a range of values ±5% of the numeric value that the term precedes. As a default the terms “about” and “approximately” are inclusive to the endpoints of the relevant range, but disclosure of ranges exclusive to the endpoints is also intended.

Also as used herein, unless otherwise limited or defined, “integral” and derivatives thereof (e.g., “integrally”) describe elements that are manufacture as a single piece without fasteners, adhesive, or the like to secure separate components together. For example, an element stamped as a single-piece component from a single piece of sheet metal, without rivets, screws, or adhesive to hold separately formed pieces together is an integral (and integrally formed) element. In contrast, an element formed from multiple pieces that are separately formed initially then later connected together, is not an integral (or integrally formed) element.

Also as used herein, unless otherwise defined or limited, the term “lateral” refers to a direction that does not extend in parallel with a reference direction. A feature that extends in a lateral direction relative to a reference direction thus extends in a direction, at least a component of which is not parallel to the reference direction. In some cases, a lateral direction can be a radial or other perpendicular direction relative to a reference direction.

The following discussion is presented to enable a person skilled in the art to make and use embodiments of the disclosure. Various modifications to the illustrated embodiments will be readily apparent to those skilled in the art, and the generic principles herein can be applied to other embodiments and applications without departing from embodiments of the disclosure. Thus, embodiments of the disclosure are not intended to be limited to embodiments shown but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of embodiments of the disclosure. Skilled artisans will recognize the examples provided herein have many useful alternatives and fall within the scope of embodiments of the disclosure.

Cooling systems can be provided for data centers to cool electrical components within a data center. During operation, electrical components, typically housed in racks having a standard rack footprint (e.g., a standard height, width, and depth), generate heat. As that heat may degrade electrical components, damage the systems, or degrade performance of the components, cooling systems can be provided for data centers for transferring heats away from racks of the data center with electrical components that need to be cooled.

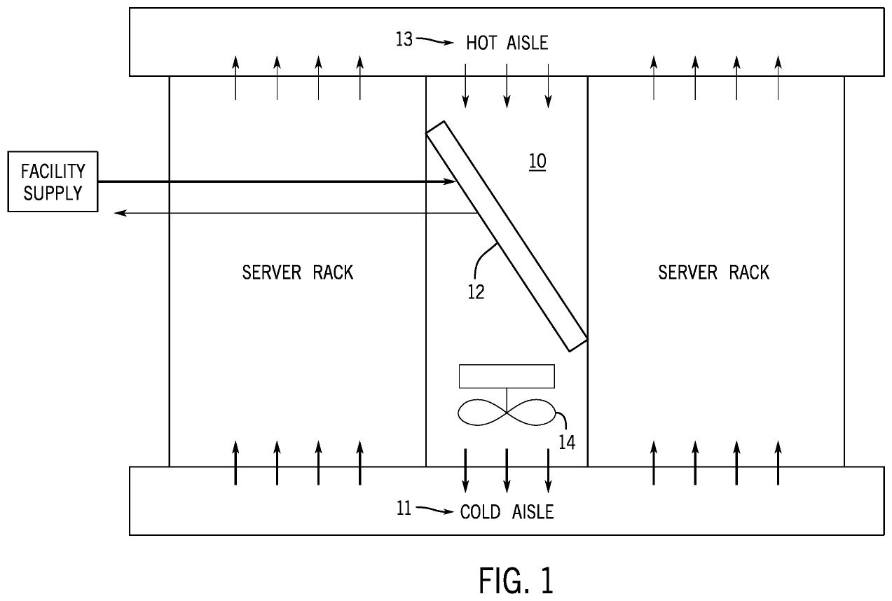

Cabinets or racks containing electrical equipment are typically arranged in rows within a data center, defining aisles between consecutive rows. Racks can be pre-assembled and “rolled in” to a space in the row adjacent to other racks, the space being pre-defined to have the footprint of a standard rack. This arrangement allows a modular construction of or addition to components in a data center. In some configurations, aisles on opposite sides of a rock of cabinets can be alternately designated as a cold aisle, or a hot aisle, and heat generated by the electrical components of a cabinet can be expelled to the hot air aisle, as shown in FIG. 1.

FIG. 1 illustrates a schematic for a cooling system, according to some embodiments of the disclosure. In the illustrated embodiment, an in-row cooling unit 10 is shown within a row of electrical equipment, with a server rack to the right and another to the left of the in-row cooling unit. As shown, the in-row cooling unit 10 is housed in a rack having a footprint that is about half of the footprint of a standard rack footprint (e.g., the in-row cooling unit has a width that is half the width of each of the server racks shown). In other embodiments, an in-row cooling unit can be housed in a rack having a standard rack footprint. Heat from cabinets housing electrical equipment (e.g., a server rack) can be transferred away from the electrical equipment into a hot aisle.

As illustrated, the cooling system (e.g., the in-row cooling unit) can be an air-to-liquid cooling system. Fans 14 can induce an airflow through the in-row cooling unit 10 in a direction toward a cold aisle 11. The airflow can draw heated air in from a hot aisle 13 into the in-row cooling unit 10. The heated air can flow across an air-to-liquid heat exchanger 12 which can cool the air by rejecting the heat to a fluid coolant. The fluid coolant can be provided by a facility and can flow into the heat exchanger 12 as a cooled liquid. The coolant can be heated in the heat exchanger 12, and the heated fluid can flow out of the in-row cooling unit 10, transferring heat away from the system. The cooled air can be expelled from the in-row cooling unit 10 into the cold aisle 11. In some embodiments, hot air can flow into the in-row cooling unit through sides of the in-row cooling unit, directly from an adjacent cabinet.

In some embodiments, an in-row cooling unit may define a front aisle. In some embodiments, the front aisle is a hot aisle. In a preferred embodiment, the front aisle a cold aisle. For example, as shown in FIG. 1, the cold aisle 11 can be defined as a front aisle. In some embodiments, the in-row cooling unit may also define a rear aisle. In some embodiments, the rear aisle is the cold aisle. In a preferred embodiment, the rear aisle the hot aisle. For example, as shown in FIG. 1, the hot aisle 13 can be defined as a rear aisle.

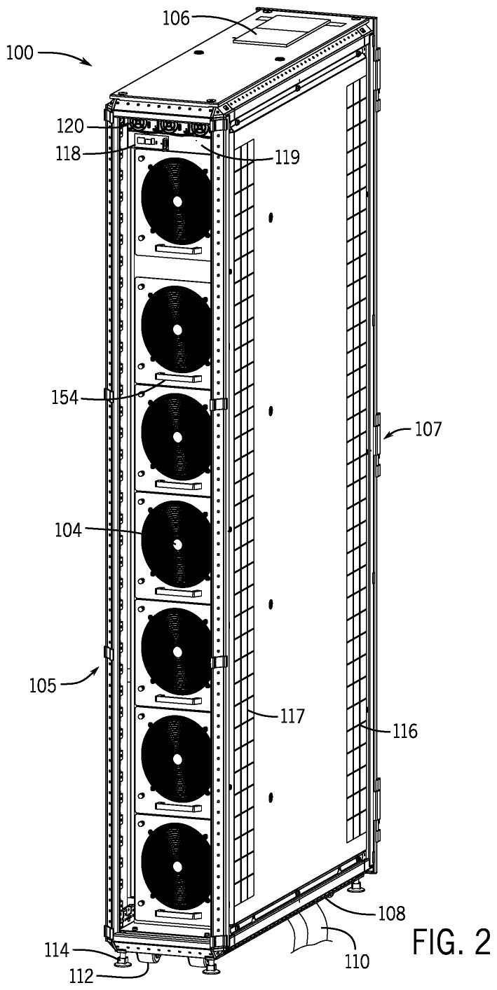

FIG. 2 illustrates an exemplary in-row cooling unit 100. As shown, the system can be housed within a cabinet having a width that is about half the width of a standard rack footprint. For example, a cabinet of an in-row cooling unit may have a width of about 300 mm (e.g., about half of the width of a standard rack within a data center). In other examples, an in-row cooling unit can define other widths. For example, an in-row cooling unit can have a width of about 600 mm, and can thus fit within a space of a data center configured to received a rack having a standard size. In some cases, an in-row cooling unit can have a width of about 900 mm or about 1200 mm. A width of an in-row cooling unit can be customized to meet spatial constraints and cooling requirements for specific applications (e.g. a custom in-row cooling unit can be provided for data centers having unique space requirements or cooling arrangements). For example, a width of an in-row cooling unit can have a positive correlation with a cooling capacity of the unit, and a width of a custom in-row cooling unit can be selected to provide a desired cooling capacity for a given data center. In some embodiments, a cabinet of an in-row cooling unit can have a height of about 2 m.

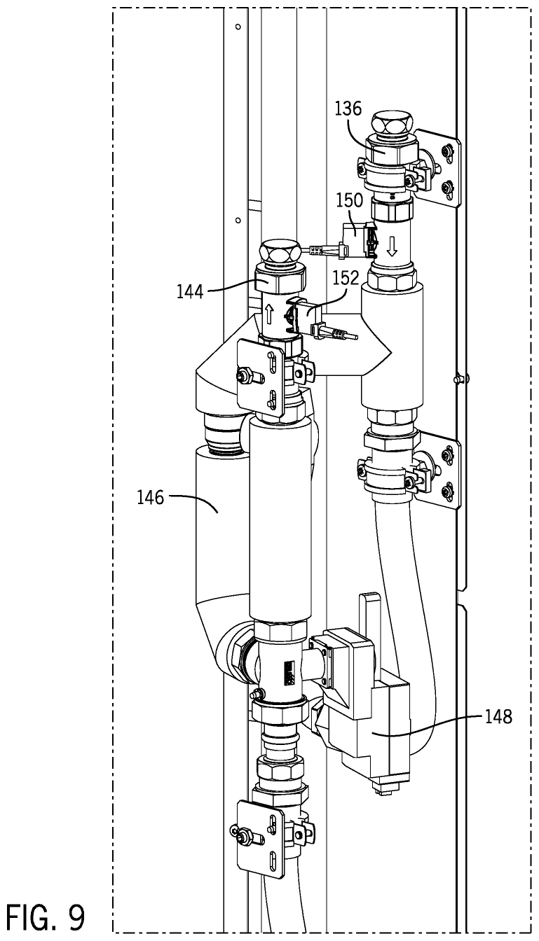

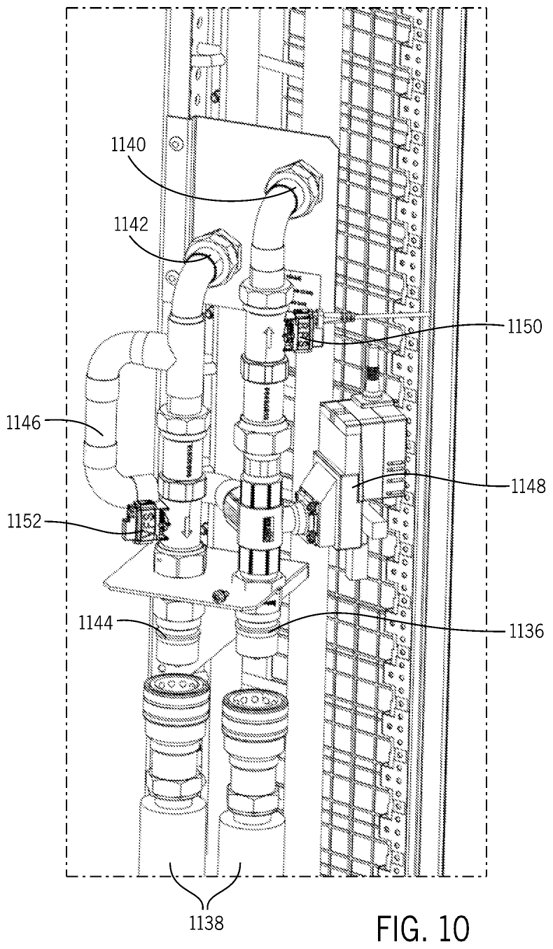

The cabinet of the in-row cooling unit 100 can include features for routing hosing for the supply lines and return lines of the cooling system. For example, as further illustrated in FIG. 2, a top-feed aperture 106 can be provided at a top of the cabinet for receiving hosing from above the unit 100. The unit 100 can also include a bottom-feed aperture 108 for receiving hosing from beneath the unit 100 into the unit 100. In the illustrated embodiment, hosing 110 of the supply line and return line are shown entering the cabinet through the bottom-feed aperture 108. In some cases, as shown in FIGS. 9 and 10 and described further below, plumbing elements within the in-row cooling unit can be arranged to accommodate one, or both of a top-feed and bottom feed configuration.

The cabinet for the in-row cooling unit 100 can also include features to aid in installation of the cabinet within a row in a data center. For example, casters 112 can be provided at a bottom of the cabinet to allow an operator to roll the cabinet into position within the row. Adjustable feet 114 can also be provided and can be adjusted to engage a floor of the data center when the cabinet is in place, to prevent displacement of the cabinet.

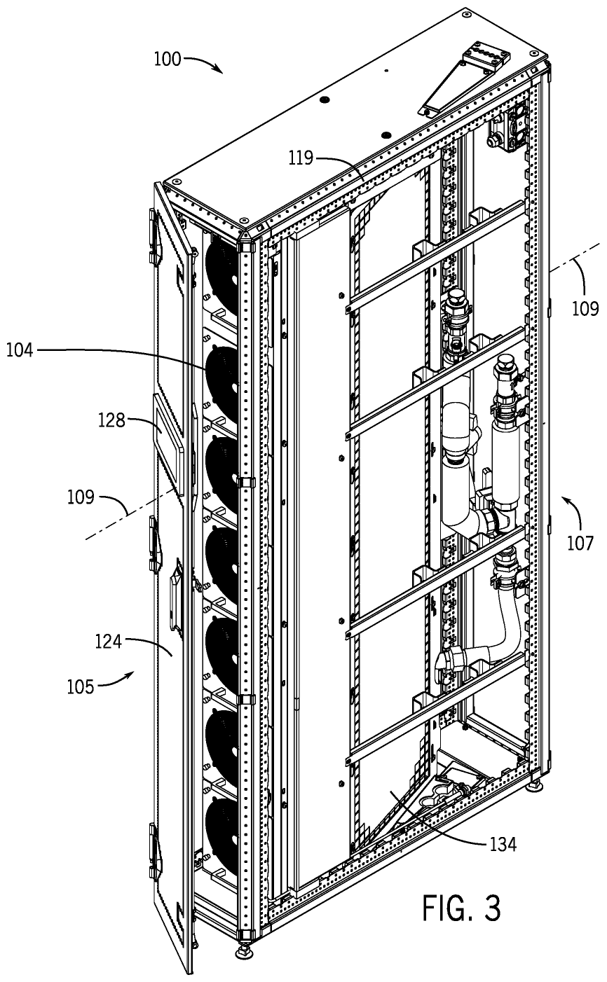

A cabinet of an in-row cooling unit can include features to allow air flow into and out of the unit in different desired directions and configurations. For example, as shown in FIG. 2, a back and a front of the in-row cooling unit 100 can be open to allow free flow of air into the back of the cabinet from a hot aisle and from the front into the cold aisle (e.g., air can flow into the unit and out of the unit in a direction transverse to a cold aisle and a hot aisle, as illustrated in FIG. 1). Additionally or alternatively, as further illustrated in FIG. 2, vents 116 can be provided in a side panel of the unit 100 to allow flow of air into the unit 100 from an adjacent cabinet of electrical equipment (e.g., a server rack). The vents 116 can also be provided on the sides of the cabinet rear 107 of the in-row cooling unit 100. Vents 117 can also be provided on sides of a front of the in-row cooling unit 100, to allow cooled air from the in-row cooling unit 100 to directly enter an adjacent rack. The vents 117 can also be provided on the sides of the cabinet front 105 of the in-row cooling unit 100. In some cases, for example, an in-row cooling unit can have one or both of a front door and a rear door (e.g., the doors 130, 124 shown in FIGS. 3, 4, and 6), which can impede a flow of air directly between an aisle and the front or rear of the in-row cooling unit. When doors are provided at one or both of a front and rear of an in-row cooling unit, air flow can be forced through vents in a side of the unit (e.g., vents 116, 117 shown in FIG. 2) to ensure that air is directly received from an adjacent rack, and cool air is provided directly to the adjacent rack. In some cases, an in-row cooling unit can include a baffle on one lateral side of the unit to prevent air-flow through all or a portion of the lateral side.

In some embodiments, an in-row cooling unit can include electronic components to increase cooling efficiency of the unit. Electronic components can include fans for inducing air flow through the unit, and flow control components for controlling fluid flow through the unit. Control systems can be provided to control fans and flow control components of the unit to achieve a desired cooling rate. For example, as further shown in FIG. 2, a plurality of fan assemblies 104 can be provided in a cabinet front 105. An air flow can be induced through the in-row cooling unit 100 (e.g., in a direction from a front of the cabinet to the rear of the cabinet, or in a direction from a rear of the cabinet to a front of the cabinet) by rotation of fans included in the fan assemblies 104, increasing the cooling efficiency thereof. In the illustrated embodiment, seven fan assemblies 104 are provided in the unit in a single column. In other embodiments, more or fewer fans or fan assemblies can be provided in an in-row cooling unit. In some embodiments, fans of an in-row cooling unit can be arranged in multiple columns (e.g., two columns), or in panels of fans. In the illustrated embodiment, a replaceable control module 118 is shown within an electrical housing 119 in a row above the fan assemblies 104. The position of the replaceable control module 118 can advantageously maintain the control module above fluid lines within the unit 100, which can prevent damage due to leakage or condensation onto the electronics of the replaceable control module 118. As described further below, the replaceable control module 118 can include a controller having instructions thereon for controlling operation of the fans of the fan assemblies 104 and flow control components (e.g., valves 148, 1148, M shown in FIGS. 9, 10 and 14 respectively) to achieve a desired cooling rate of air flowing through the in-row cooling unit 100.

In some embodiments, power control components can also be provided within an electrical housing in a top of a cabinet. For example, as further illustrated in FIG. 2, three power supply units 120 can be provided in a top of the cabinet (e.g., as illustrated further in FIG. 5). Each power supply unit 120 can correspond to a power inlet (e.g., power inlets 122 shown in FIG. 7), and can be configured to transform the voltage received from the corresponding power inlet into a desired voltage. For example, electrical power can be received at the inlet at 120 V, and each power supply unit 120 can be configured to transform the power to 48 V. Further, power received at the power supply units 120 can be received as an AC voltage, and the power supply units 120 can transform the power, and output the power as a DC voltage. In some embodiments, the power supply units can be configured to transform different supply voltages to different voltage values, including as may be required to adapt to power supply standards in different countries or regions. In some embodiments, an in-row cooling unit can include more than three power supply units or less than three power supply units. In some embodiments, an in-row cooling unit can operate when two power supply units are operational (e.g., the power supply units 120 can be configured to operate in a N+1 redundancy mode), as can allow the in-row cooling unit to continue cooling when a single power supply unit is removed for maintenance or is otherwise offline (e.g., due to a fault). In some embodiments, the power supply units are not connected to a network, and the power supply units may be able to function independently of one another. For example, one power supply unit may be shut off for maintenance, but the other power supply units may still remain in operation. Further, the electrical power may be shut off via an input from the local system, e.g., an input that originates from the in-row cooling unit and not a network. For examiner, each of the power supply units 120 can be in electronic communication with the controller of the replaceable control module 118, and can be controlled according to instructions from the controller. The controller can control a redundancy mode, an output voltage, or other power characteristics, and can receive status information from the power supply units 120 (e.g., an error code, and on/off status, etc.). The power supply unit 120 can be in communication with the controller of the replaceable control module 118 via a Modbus connection.

As shown in FIG. 2, each of the power supply units 120, the control module 118 and the fan assemblies 104 are mounted at a front face of cabinet. A front-facing portion of each of the control module 118, the power supply units 120 and the fan assemblies 104 are generally flush with the front face of the cabinet (e.g., generally coplanar along a vertical plane), though portions of one or more of the control module 118, the power supply units 120 and the fan assemblies 104 can be inset relative to the front face, or can extend beyond the front face (e.g., the handles 154).

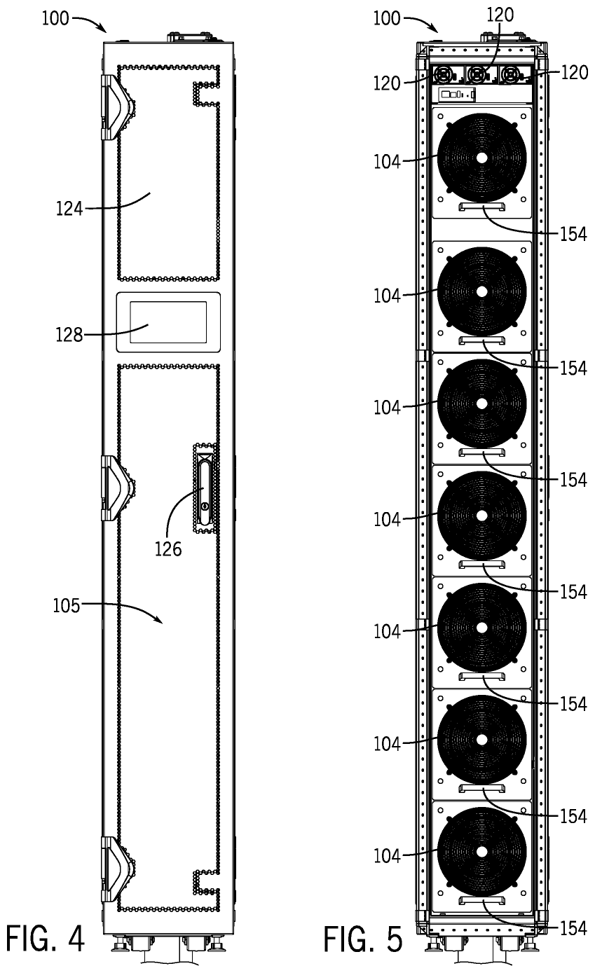

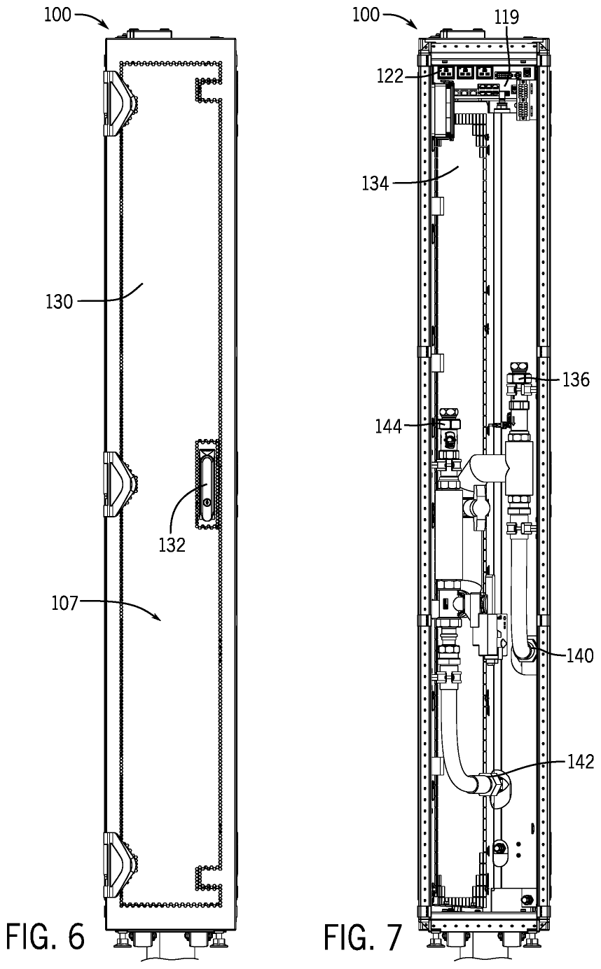

In some embodiments, an in-row cooling unit can include doors to enclose the elements of the unit, and to direct flow of air into and out of the unit. For example, as illustrated in FIG. 3, a front door 124 can be provided at a front of the cabinet 105. The front door can include a lockable handle 126 to protect components of the unit 100 and allow only authorized access to the unit 100 and components therein (e.g., the fans, power supplies, and control module). A panel 128 can be provided (e.g., a touch screen panel) in the door 124, which can face a cold aisle (e.g., the cold aisle 11 shown in FIG. 1). The panel 128 can display user interfaces to an operator of the in-row cooling unit 100 and can allow the user to monitor conditions of the unit 100, provide instructions (e.g., power on/power off the unit), and set operating parameters. In some embodiments, the panel 128 can display a plurality of user interfaces, e.g., a power on/power off button, readings from the in-row air unit, control features, input features to power on/off components such as a power supply, and other interfaces of the like. When the front door 124 is installed or when the front door 124 is in a closed position (e.g., as shown in FIG. 4), at least a portion (e.g., substantially all) of the cooled air can exit the unit 100 through the side vents 117 (e.g., illustrated in FIG. 2). As shown in FIG. 6, a rear door 130 can be provided in a rear of the unit 100, or a cabinet rear 107, and can also protect components accessible through the cabinet rear 107, or rear of the unit 100 (e.g., piping elements, flow control elements, sensing elements, etc.). The rear door 130 can also include a lockable handle 132 to restrict access to the unit to authorized individuals. In some embodiments, an in-row cooling unit can not include a rear door, which can allow air to flow directly into the unit from the rear thereof, e.g., the cabinet rear does not include a rear door, and air flows directly through the cabinet rear. In some embodiments, apertures, vents, or other flow control elements can be provided in either or both of the front or rear doors 124, 130 to allow air flow into the unit 100 through the rear and out the cabinet front 105 of the unit 100. In some embodiments, when the doors 124, 130 are in a closed position, air can flow into the unit 100 through the vents 116, 117 on the sides of the cabinet. In some embodiments, baffles can be provided at one or more sides of an in-row cooling unit to prevent air flow in a given direction.

Referring now to FIG. 7, power inlets 122 can be provided at a rear of the in-row cooling unit 100 within the electrical housing 119, to receive power cables of the facility to power electrical components of the unit 100. In the illustrated embodiment, there are three power inlets 122, but other embodiments can include more than three or less than three power inlets. Each power inlet 122 can be in electronic communication with a corresponding power supply unit 120 (e.g., shown in FIGS. 2 and 5), and the corresponding power supply unit 120 can transform the voltage received at the inlet 122 (e.g., 120 V AC) to a desired voltage (e.g., 48 V DC).

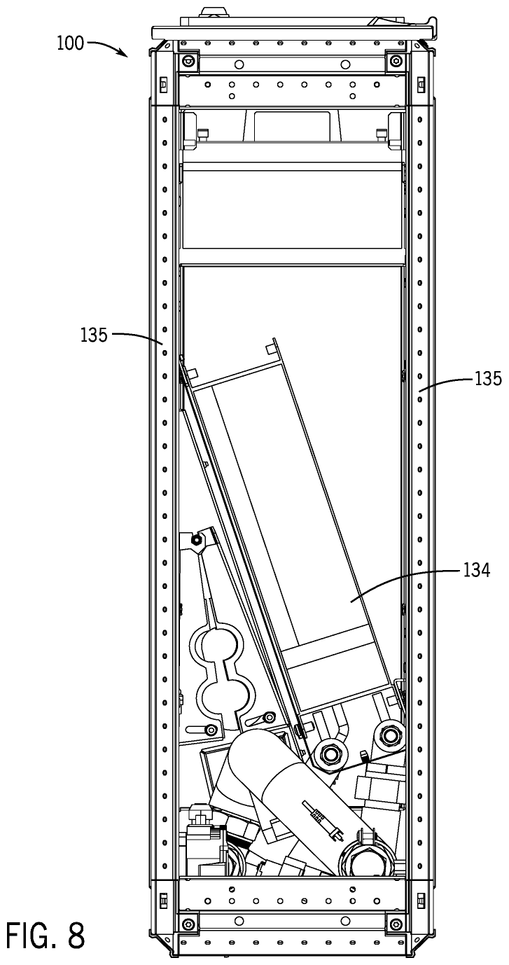

An in-row cooling unit can include heat transfer components, piping elements, and flow control elements to facilitate heat transfer from the air flowing through the unit to a fluid (e.g., a fluid supplied by a facility). For example, as shown in FIG. 3, an air-to-liquid heat exchanger 134 can be housed in the unit 100 and can extend vertically from a bottom of the unit 100 to the electrical housing 119 so that substantially all air flowing through the unit 100 traverses the heat exchanger 134, which increases a heat transfer efficiency of the unit 100. In some embodiments, a heat exchanger can be positioned within an in-row cooling unit to maximize a surface area through which air flows, thus further increasing a heat transfer efficiency. For example, as shown in FIG. 8, the heat exchanger 134 can be positioned at an oblique angle within the unit 100 relative to lateral side panels 135 of the in-row cooling unit, as can advantageously increase a surface area of the heat exchanger 134 through which air flows. In other embodiments, the heat exchanger may be positioned at an acute angle within the unit relative to the lateral side panels of the in-row cooling unit. An in-row cooling unit can include mechanical features (e.g., baffles, duct structures, etc.) prevent air leakage and direct all or substantially all air flowing through the unit through the heat exchanger. For example, in some cases, baffle plates can be provided at lateral sides of an in-row cooling unit, to prevent air upstream of the heat exchanger from escaping the in-row cooling unit before flowing over the heat exchanger to be cooled.

With continued reference to FIG. 8, a front portion of the in-row cooling unit can be defined at a front side of the heat exchanger (e.g., downstream of a direction of air flow across the heat exchanger 134) and a rear portion of the in-row cooling unit 100 can be defined at a rear side of the heat exchanger 134 (e.g., upstream of an air flow across the heat exchanged 134). In some examples, an axis can be defined that extends through a front and a rear of a cabinet of an in-row cooling unit. For example, as illustrated in FIG. 3, axis 109 defined in a direction extending between the cabinet front 105 and the cabinet rear 107. As shown, the axis 109 is orthogonal (e.g., normal, perpendicular, at a right angle to, etc.) to the cabinet front 105 and orthogonal to the cabinet rear 109. Further, the axis 109 runs parallel to the lateral side panels 135. Air-flow can be provided through the in-row cooling unit 100 in a direction parallel to axis 109 (e.g., as shown in FIG. 1). Further, as described below, hot-swappable components of the in-row cooling unit 100 (e.g., the fan assemblies 104, the replaceable control module 118, and the power supply units 120) can be removed from and inserted into the in-row cooling unit 100 in an insertion direction parallel to the axis 109.

Returning to FIG. 7, plumbing elements (e.g., piping, hosing, valves, etc.) can be provided in an in-row cooling unit to allow flow of fluid through the unit to transfer heat from the air flowing through the unit to the fluid flowing through the piping. In this regard, a fluid inlet 136 (e.g., a supply) of plumbing of the in-row cooling unit 100 can receive fluid (e.g., water) from the facility from hosing. The hosing can be flexible hosing to allow top-feed or bottom-feed installations of the unit 100. In some embodiments, quick-connect fittings can be provided at the inlet to allow a tool-less installation of the hosing to the fluid inlet 136. Fluid from the fluid inlet 136 can flow into the heat exchanger 134 at a heat exchanger inlet 140 and can be heated in the heat exchanger 134 by transfer of heat from the air flowing across the heat exchanger 134. The fluid can then flow out of the heat exchanger 134 at a heat exchanger outlet 142 and can continue to flow to a fluid outlet 144 (e.g., a return) of the in-row cooling unit 100. The fluid outlet 144 can include a quick connect-fitting (e.g., similar to the inlet) to allow toolless installation of hosing to the fluid outlet 144, and fluid can flow through hosing to exit the unit 100, thus transferring heat away from the unit. In some cases, the plumbing elements and the heat exchanger 134 can be adapted to receive a flow of water coolant. In some case, materials, pipe diameters, plumbing configurations, seals, and other plumbing elements of an in-row cooling unit can receive a glycol-water mixture. In an example, a liquid coolant receivable into the plumbing elements of the in-row cooling device can be a water-glycol mixture with up to 35% glycol by weight.

In some embodiments, an in-row cooling unit can include flow control elements along piping of the unit to allow flow of the fluid to be controlled by an operator or controller of the in-row cooling unit (e.g., to allow or stop flow through portions of piping of the in-row cooling unit, or to achieve target values for operational parameters). As shown in FIG. 9 a bypass line 146 can be provided in the piping of the unit 100 and can allow fluid to bypass the heat exchanger 134 and flow directly from the fluid inlet 136 to the outlet 142. A valve 148 can be provided along the bypass line 146 (i.e., downstream of fluid inlet 136 and upstream of heat exchanger inlet 140) and can control a flow through the bypass line 146. The valve 148 can be controllable by a controller of the unit 100 (e.g., the controller housed in the removable control module 118 shown in FIGS. 2, 5, 11, and 12) can alternate between an open position, a partially open position, and a closed position (e.g., where no flow is allowed through the bypass line 146). In some embodiments, including as illustrated, the valve 148 can also control flow of fluid to the heat exchanger 134. For example, if the valve 148 is fully open, the valve can shut off fluid flow through the heat exchanger 134 and only allow flow through the bypass line 146. When the valve 148 is in the partially open position, it can permit a portion of the fluid to flow through the bypass line 146 and a portion of the fluid to flow through the heat exchanger 134. When the valve 148 is in the closed position, all fluid flow can be directed through the heat exchanger 134. In some embodiments, the valve 148 can include another position to fluidly isolate the inlet from fluid flow and prevent flow into either of the heat exchanger 134 and the bypass line 146. In some embodiments, multiple valves can be provided along piping of an in-row cooling unit to selectively allow, throttle, or deny flow through portions of the piping. For example, a two-way valve can be provided along a bypass line and another two-way valve can be provided along the inlet, and the valves can be independently operated to permit or deny flow through the inlet (e.g., into the heat exchanger) or through the bypass line. In some embodiments, valves along the piping of an in-row cooling unit can be manually operated, and an operator can change the position of the valve to achieve desired flow configurations.

In some embodiments, an in-row cooling unit can include sensing elements to monitor operating parameters of the fluid flow (e.g., temperature, pressure, flow rate, etc.). Measured values of operating parameters can be reported to operators of the in-row cooling unit (e.g., through alerting, logging, at a panel of the in-row cooling unit, via an API, UI, or other interface) and in some embodiments, electronic components of the in-row cooling unit (e.g., fans and valves) can be controlled in response to measured operating values to achieve set points for operating parameters, as discussed below. For example, as further shown in FIG. 9, an inlet sensor 150 can be provided along the fluid inlet 136 and an outlet sensor 152 can be provided along the fluid outlet 144. The sensors 150, 152 can measure any or all of temperature, pressure, or flow rate of fluid through the respective portions of the piping. In some embodiments, the sensors 150, 152 can measure other operating parameters of the fluid flowing through the piping. In some embodiments, additional sensors can be provided along the piping, to sense operating parameters at different points along the flow path of the fluid. Set points can be set in a controller of the in-row cooling unit 100 for operating parameters of either or both of the sensors 150, 152, or for a differential of the operating parameters sensed by the respective sensors 150, 152 (e.g., a differential temperature between the inlet and the outlet). In some embodiments, as described below, one or more of a flow rate of air across the heat exchanger or a flow rate of fluid through the heat exchanger can be controlled in response to sensed parameters to achieve desire cooling efficiencies or set points for operating parameters at points along the unit.

In some embodiments, it may be advantageous to have an in-row cooling unit in a bottom feed configuration, as shown in FIG. 10. In many aspects, the bottom feed configuration of the in-row cooling unit shown in FIG. 10 contains substantially similar components to that of the in-row cooling unit shown in FIG. 9. As such, the components of FIG. 10 contain similar numbering in the 1000 series as the in-row cooling unit shown in FIG. 9. For instance, the sensor 150 of FIG. 9 is a sensor 1150 in FIG. 10. Additionally, a fluid inlet 1136 and a fluid outlet 1144, which are substantially similar to fluid inlet 136 and fluid outlet 144, each include a quick-connect fitting, which allows both the fluid inlet 1136 and the fluid outlet 1144 to be quickly and easily disconnected from a hosing 1138. The hosing 1138, in some embodiments, is substantially similar to the hosing described above. In some embodiments, other fittings are used between the fluid inlet 1136, fluid outlet 1144, and hosing 1138.

In some embodiments, an in-row cooling unit can include features to ensure continual operation during component failures, and during maintenance of components of the unit (e.g., components can be “hot-swappable”). It can be particularly advantageous to position hot-swappable electronic components of an in-row cooling unit at a single side of the unit, as can allow an operator to easily access and service the hot-swappable electronic components (e.g., without the need to disassemble the unit). For example, electronic components (e.g., hot-swappable fans, control modules, and power supply units) can be positioned on a side of an in-row cooling unit opposite a side at which electrical, plumbing, and network connections engage the rack. This arrangement can advantageously simplify an access to components, and reduce a risk of disconnection of electrical, plumbing, and network connections of the unit when an operator attempts to service hot-swappable electronic components. For example, in some embodiments, hot-swappable components of an in-row cooling unit (e.g., a control module, a fan, a power supply unit, etc.) can be accessed from a front of an in-row cooling unit (e.g., from a cold aisle side of the in-row cooling unit). In some examples, hot-swappable components of an in-row cooling unit can be accessed (e.g., removed, installed, or serviced) at a rear of the row cooling unit (e.g., from a hot aisle of the in-row cooling unit). In other embodiments, when a component of the in-row cooling unit (e.g., a control module, a fan, a power supply unit, etc.) is hot-swappable, the component may be removed from the in-row cooling unit via the front aisle of the in-row cooling unit (e.g., the cold aisle, illustrated in FIG. 1). In the illustrated examples of FIGS. 2, 3, and 5, the in-row cooling unit defines a front face at the front 105 of the cabinet, and each of the fan assemblies 104, the control module 118, and the power supply units 120 are positioned along the front face, as can advantageously allow for servicing of these components from the cold aisle of the data center. The components of the in-row cooling unit may be removed along the axis 109. In other words, the components may be hot-swappably removed from the cabinet front 105, or the cabinet rear 107, during operation of the in-row cooling unit. The axis 109 allows components to be removed from the in-row cooling unit a straight path (e.g., along the insertion direction parallel to the axis 109). The removal of the components along the axis 109 is advantageous as the axis allows the components to be removed into an area (e.g., the front or rear aisle) that has space to comfortable maneuver and perform maintenance on the removed components and/or the in-row cooling unit. In other words, it is advantageous for the in-row cooling unit to have a front, or rear, aisle which allows for components (e.g, hot-swappable components, control module, fan, power supply unit etc.) to be removed from the same side, or same aisle, or the in-row cooling unit.

Electronic components of an in-row cooling unit can be configured for toolless removal and installation, as can further simplify a servicing of the in-row cooling unit. For example, electronic components can include blind mate connectors to allow for toolless installation and removal of the components, and the blind-mate connectors can engage corresponding connections of the in-row cooling unit when the electronic component is appropriately aligned upon installation. In some cases, electronic components can include handles to facilitate insertion and removal of the electronic component from the in-row cooling unit.

For example, the fan assemblies 104 (e.g., shown in FIGS. 2 and 5) can include handles 154 to allow removal and installation of the fan assemblies 104, and each fan assembly 104 can be individually removed during operation of the in-row cooling unit 100. The handles 154 can facilitate a hot-swappable and toolless installation and removal of the fan assemblies 104 from the in-row cooling unit 100 (e.g., the fans may be removed during operation of the in-row cooling unit 100 without interrupting an operation of the in-row cooling unit 100). In some cases, a controller (e.g., the controller of the removable control module 118) of the in-row cooling unit 100 can increase a speed of the fans of the installed fan assemblies 104 when an individual fan is removed to maintain an air flow rate or a heat transfer rate of the unit 100 to minimize the impact of the removal of the fan. In some embodiments, the fan assemblies 104 include blind mate connectors, which can allow toolless installation and removal of the fans. Shutters (not shown) can be provided for each fan of the in-row cooling unit 100 and can automatically block an air flow through fan space when one of the fan assemblies 104 is removed from the fan space. When a fan assembly 104 is installed into a fan space, the shutter can be opened to allow air flow through the installed fan assembly 104.

Power control components of an in-row cooling unit can also be hot-swappable and can provide redundancy to ensure that failure of a power control component does not cause the in-row cooling unit to cease operation. For example, FIG. 10 illustrates the electronics housing 119, which, as shown, houses the power supply units 120 and the controller module 118. In the illustrated embodiment, there are three power supply units 120. In other embodiments, an electrical housing for an in-row cooling unit can include more than three or fewer than three power supply units. In the illustrated embodiment, the power supply units 120 are provided with N+1 redundancy (e.g., the in-row cooling unit requires two operational power supply units 120 to be operational and can operate while one power supply unit is removed or otherwise not functioning). The power supply units 120 can include blind mate connectors to allow for toolless removal and installation of the power supply units 120.

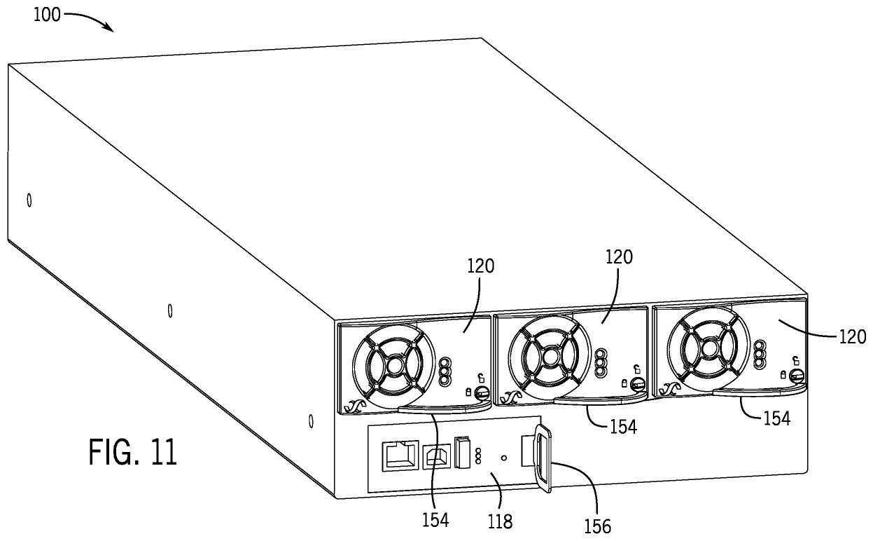

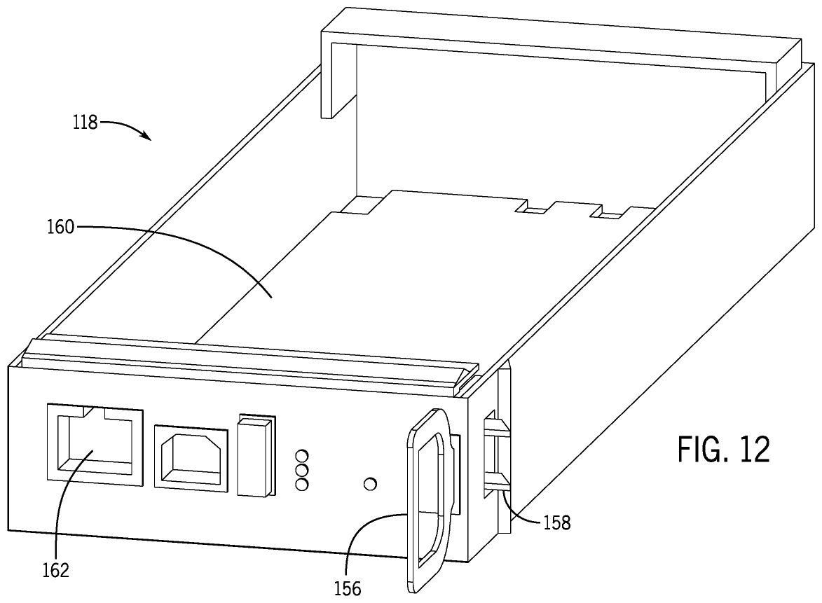

A control module for controlling electronic components of an in-row cooling unit can be configured for toolless installation and removal. Further, an in-row cooling unit can include systems and processes for maintaining operation of the unit when a controller (e.g., housed in a control module) is removed from the unit for removal or replacement. For example, as shown in FIG. 11, the control module 118 housing the controller of the in-row cooling unit 100 can include a latch handle 156. The latch handle 156 can provide a contact point to facilitate removal of the control module 118 from the electrical housing 119. In some embodiments, the latch handle 156 can be displaced in a lateral direction, e.g., orthogonal to an insertion direction of the control module 118 into the electrical housing 119 to release a latching mechanism and allow removal of the control module 118. In some embodiments, the lateral direction may be parallel to the axis 109. For example, FIG. 12 illustrates the control module and show teeth 158 of the latch handle 156 extending outwardly from the control module in a lateral direction. When the control module 118 is installed in the electrical housing 119, the teeth can engage features of the electrical housing 119 to oppose removal of the control module 118 from the electrical housing 119. When the latch handle is displaced in a direction that is opposite the direction the teeth 158 extend, the teeth 158 can disengage the feature of the electrical housing 119, and the control module 118 can be removed from the electrical housing 119. In other embodiment, other retention mechanisms can be included in a control module to secure the control module 118 in the electrical housing 119. In some embodiments, a control module does not include a retention mechanism. In some embodiment, the control module includes blind mate connectors to connect the controller to electrical components of an in-row cooling unit.

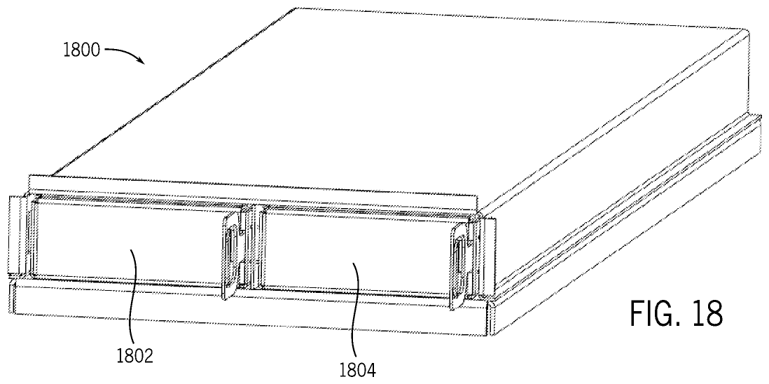

In some cases, more than one control modules can be provided for an air-to-liquid cooling unit. For example, an air-to-liquid cooling unit can include two control modules, each including a respective controller. The controllers of the two control modules can be configured to operate in a redundant mode (e.g., active-passive, fail-over mode, alternating primary mode, etc.). FIG. 18, for example illustrates a control module assembly 1800 including a first removable control module 1802 and a second removable control module 1804. The control module assembly can be installed in an air-to-liquid cooling unit (e.g., air-to-liquid cooling unit 100 shown in FIG. 2), and can allow a control system of the unit to operate in a redundant mode. For example, in normal operation the controller of control module 1802 can be a primary controller and can control operation of fans, valves, power supply units, and other electronic components of the unit. When the control module 1802 is removed, the electronic components of the air-to-liquid cooling unit can be controlled by the controller of the control module 1804. In some cases, an air-to-liquid cooling unit can include more than two hot-swappable control modules. In some cases, controllers of different control modules of an air-to-liquid cooling unit can have different instructions to operate the unit in different cooling modes according to which of the controllers is a primary controller.

A control module for an in-row cooling unit can comprise a main (e.g., an intelligent) microcontroller and a passive interface board. For example, as further illustrated, the control module 118 can house a controller 160 (e.g., a PLC controller), and can include interfaces (e.g., USB, Ethernet, etc.) on a front face thereof, to allow wired connection to the control module 118 for obtaining or programming values. An interface board for inputs and outputs can also be provided in the control module 118 for connection to electronic components of the in-row cooling unit (e.g., the hot-swappable fan assemblies 104, power supply units 120, the valve 148, sensors of the in-row cooling unit 100, etc.). For example, the controller 160 can control a speed of fans of the respective fan assemblies 104 or position of the valve 148 along a fluid flow path in response to system parameters, as described further below.

An interface board for use with the in-row cooling unit can include connections for sensors of a sidecar system. The board can have a 1Gbe network interface for connecting to other components within the datacenter, and a user can access the interface through an LCD output provided on the unit, or through a web interface. In addition to the ethernet connection described above, the interface board can have ports for receiving sensor data, including analog or digital data. The board can provide monitoring capabilities for monitoring sensor values against set values and can provide alerting when the sensor values fall outside of a safe operating region defined in the system. In an example, the interface can provide three sensor management ports, with each port being capable of monitoring up to 16 sensor devices. A total length of cable connected to each port can be 40 meters, for example. The interface board can support multiple industry standard protocols for communication and alerting, e.g., SNMP, SMTP, HTTPS, BACnet, Modbus/TCP, and HPI. The interface board can include USB ports and analog and digital input ports to directly read sensors, for example, sensors with an output of 10 volts.

In some embodiments, the controller 160 is configured to control one or more of a position of the valve 148 and speed of the fans of the fan assemblies 104 when the controller 160 is installed. In some embodiments, the controller can control fan speed of fans of the fan assemblies 104 and a position of the valve 148 in response to sense parameters (e.g., a humidity of the air, a temperature of the air, a temperature of the fluid, a differential temperature of the fluid across the heat exchanger 134, a flow rate of fluid through the in-row cooling unit 100, etc.). In the case of a failure of components of the control module 118 (e.g., the controller 160, interfaces 162, etc.) or when the control module is removed for maintenance or replacements, communication to electrical components (e.g., fans and valves) of the in-row cooling unit 100 can be lost. In some embodiments, then, the fans 108 can include integrated local controllers (as describe below) to control a speed of the fans when a connection to the controller 160 is lost. Additionally, the valve 148 can revert to a default position (e.g., fully closed to allow all flow through the heat exchanger, or partially closed to allow a set proportion of flow through the heat exchanger and the bypass loop respectively) when a communication with the controller 160 is lost. In some embodiments, a position of a valve can remain the same as when communication to a controller was lost, to maintain the system in a similar state. Thus, the control module 118 can be hot-swappable during operation of the in-row cooling unit 100 without causing operation of the unit 100 to cease.

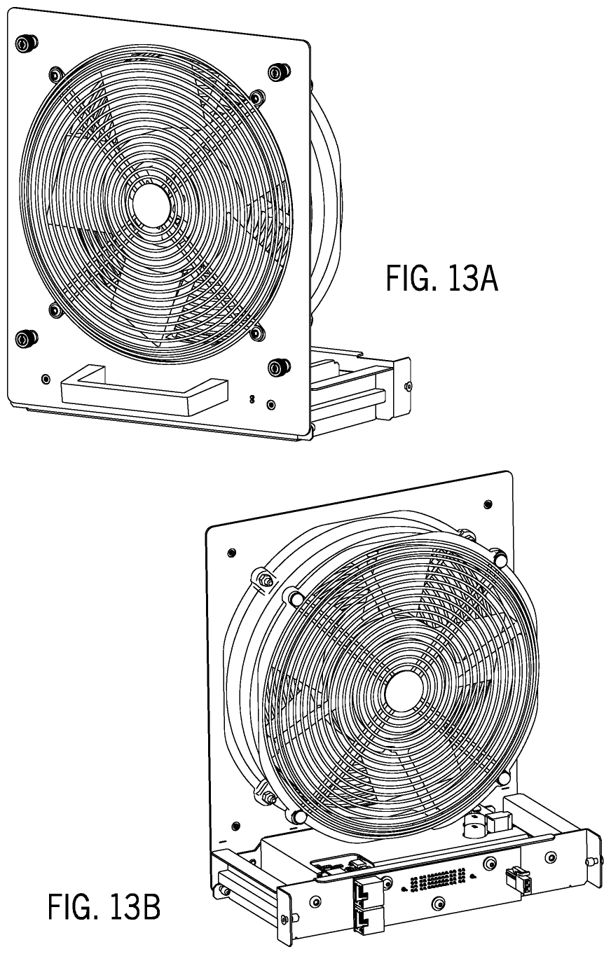

FIG. 13A illustrates an embodiment of an individual fan module. FIG. 12B further illustrates the fan module of FIG. 13A. In some embodiments, the fan module is substantially identical to the fan assembly 104. The fan module can include an impeller mounted on a back side of a modular unit, e.g., a fan module. The fan modules can be easily removable with a handle and can include blind mate connectors. The handle of the fan module is substantially similar to the handle 154 of the fan assembly 104. The fan modules can be removed and replaced while the sidecar unit remains operating, e.g., the fan modules are hot-swappable. As described below, each fan module can include a fan controller module and sensors (e.g., temperature and humidity sensors). In regular operation (e.g., when the fan is in communication with the controller 160) the fan controller module can receive instructions from the controller 160 to control a speed of the fan. When connection to the controller 160 is lost, the fan controller module can maintain fan speed at a set speed or vary fan speed based on sensed parameters from sensors integrated with the fan module.

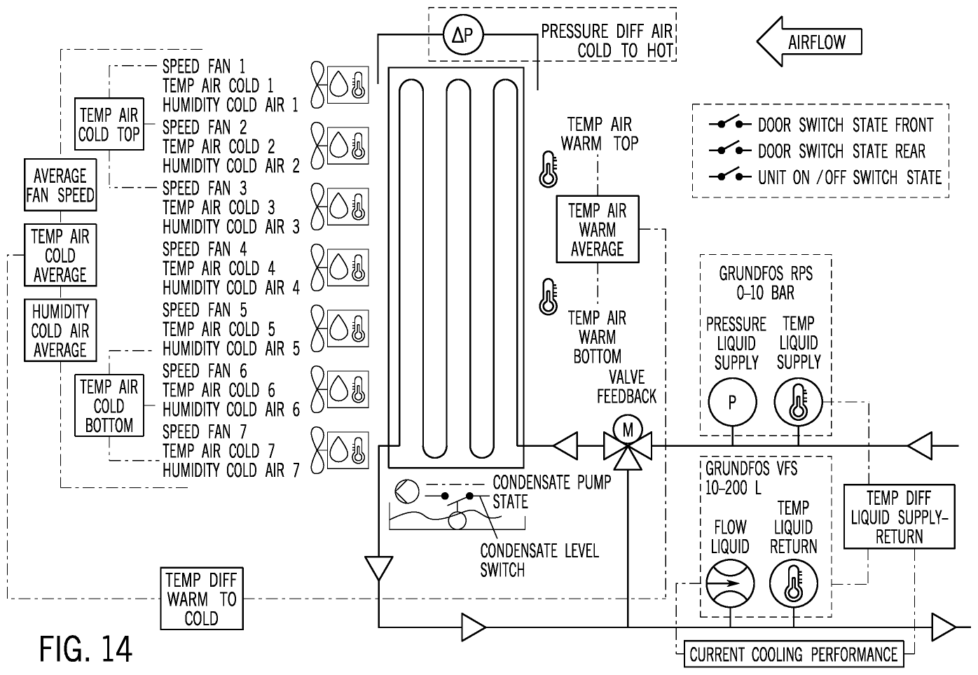

FIG. 14 is a system diagram for liquid to air heat exchanger connected to a water supply, such as a pressurized water supply for a building. The system includes a liquid return line that passes a sensor module including a pressure liquid supply sensor and a temperature liquid supply sensor. The liquid passes through a three-way motorized valve M (e.g., valve 148) before entering the heat exchanger (e.g., heat exchanger 134, illustrated in FIG. 2) with a temperature air warm top sensor and a temperature air warm bottom sensor. The heat exchanger further includes a pressure differential air cold to hot sensor. The liquid to air heat exchanger can include seven fan modules. Some embodiments can include fan modules with one, two, or four fans. Each of the fans placed adjacent to the heat exchanger can include three sensors, including a fan speed sensor, a temperature air cold sensor, and a humidity cold air sensor. The sensed parameters can be analyzed by a control system to calculate a number of parameters, such as temperature air cold top, average fan speed, temperature air cold average, humidity cold air average, temperature air cold bottom, and temperature differential warm to cold. The liquid exits the heat exchanger and flows past a final set of sensors including a liquid flow rate sensor and a temperature liquid return sensor. Additional parameters can be calculated, including temperature differential supply-return and current cooling performance. The system can further include a condensate pump, the state of which can be monitored by calculating the parameters noted above, the status of which can be controlled using a condensate level switch.

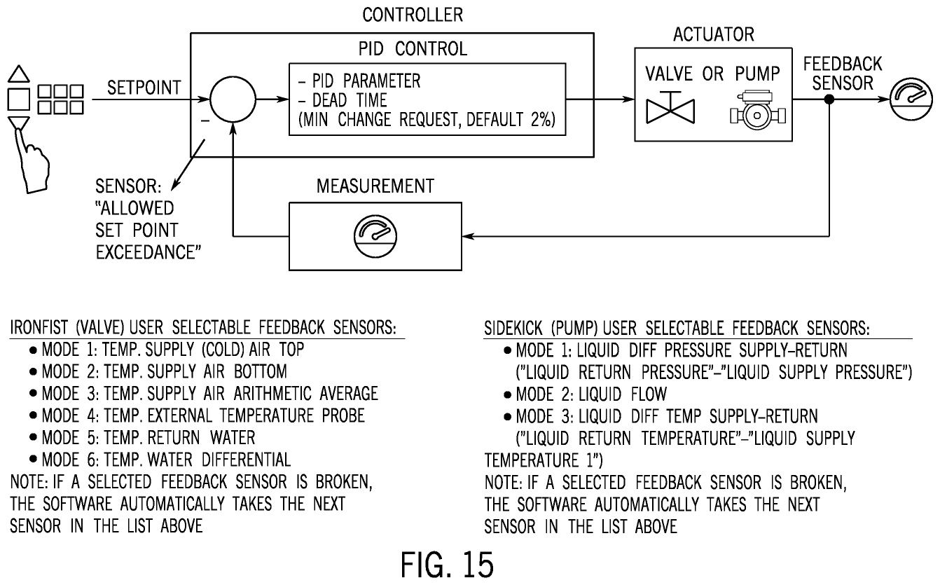

FIG. 15 illustrates a feedback control system for the air-to-liquid heat exchange system of FIG. 14, in which the bypass valve (e.g., the valve 148 shown in FIG. 9) serves as the actuator. In some embodiments the system operates according to a proportional integral derivative (PID) control. The PID feedback control system can operate in multiple modes (e.g., can control flow of fluid to achieve set points for different operating parameters). For example, as shown, the feedback control system can be operated by a controlled (e.g., controller 160) to control the valve in one or more modes. For example, in the illustrated Mode 1, the valve 148 can be controlled to achieve a set point for a sensed temperature of air at a top of the unit 100 (e.g., as sensed by temperature sensors of fan assemblies 104 of the unit). In Mode 2, the valve 148 can be controlled to achieve a set point for a sensed temperature of air at the bottom of the unit 100. In Mode 3, the valve 148 can be controlled to achieve a set point for an arithmetic average of temperatures between the temperature at the top of the unit 100 and the bottom of the unit 100. In Mode 4, the valve 148 can be controlled to achieve a set point for a temperature sensed external to the unit 100 (e.g., a temperature of air in the cold aisle illustrated in FIG. 1). In Mode 5, the valve 148 can be controlled to achieve a set point for a temperature of fluid at the fluid outlet 144 (e.g., a return). In Mode 6, the valve can be controlled to achieve a set point for a differential temperature of a fluid between the fluid inlet 136 and the fluid outlet 144. In some embodiments, if a sensor required to operate a given mode is defective, the feedback control system can switch to another mode. In some embodiments, an operator of the unit 100 can select an operating mode for the unit 100.

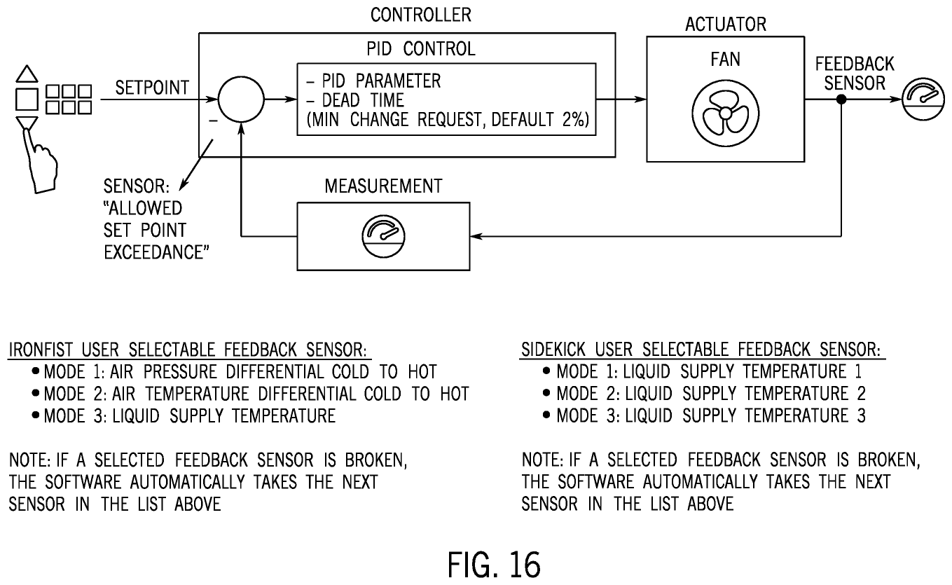

FIG. 16 illustrates a feedback control system for the air-to-liquid heat exchange system of FIG. 14, in which the fans serve as the actuators. In some embodiments, the feedback control system operates according to proportional integral derivative control. For the air-to-liquid heat exchanger unit of FIG. 14, the feedback control system can include three modes, namely Mode 1 based on air pressure differential cold to hot, Mode 2 based on air temperature differential code to hot, and Mode 3 based on liquid supply temperature.

In some embodiments, the feedback control system attempts to achieve relatively constant liquid flow rate through the system. The feedback control system relies on the differential air temperature on the air side and the water side of the heat exchanger. The feedback control system also relies on the pressure differential on the liquid side. The feedback control system balances the liquid and air flow rates to achieve the desired heat rejection. In some embodiments, if the temperature on the liquid side becomes hot (e.g., above a fluid heat threshold value), the speed of the fans can be increased, and/or the position of the bypass valve can be opened to allow maximum flow of fluid through the heat exchanger to achieve maximum cooling capacity. In some embodiments and in certain modes, flow of fluid through the heat exchanger is increased first before fan speed is increased.

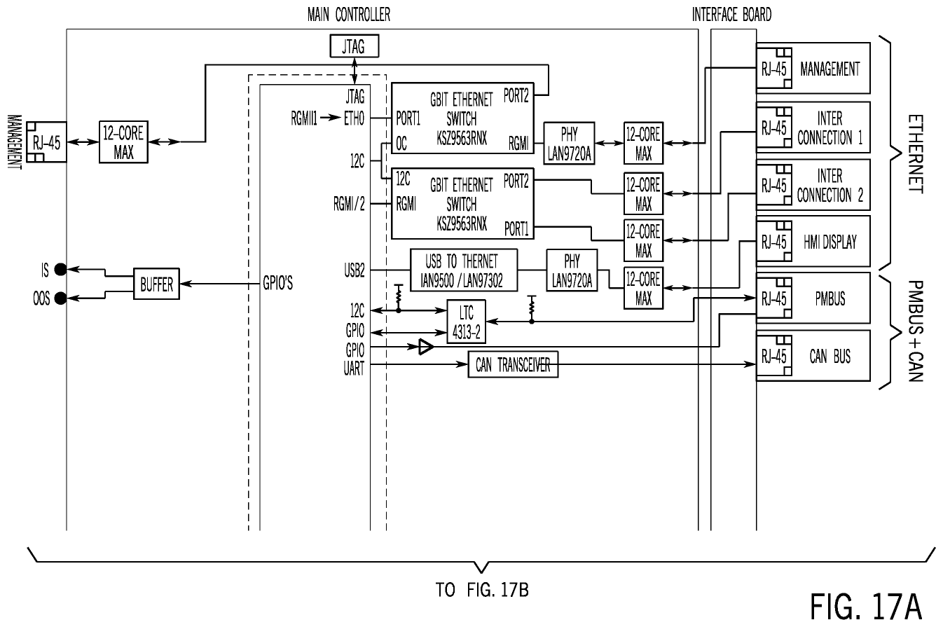

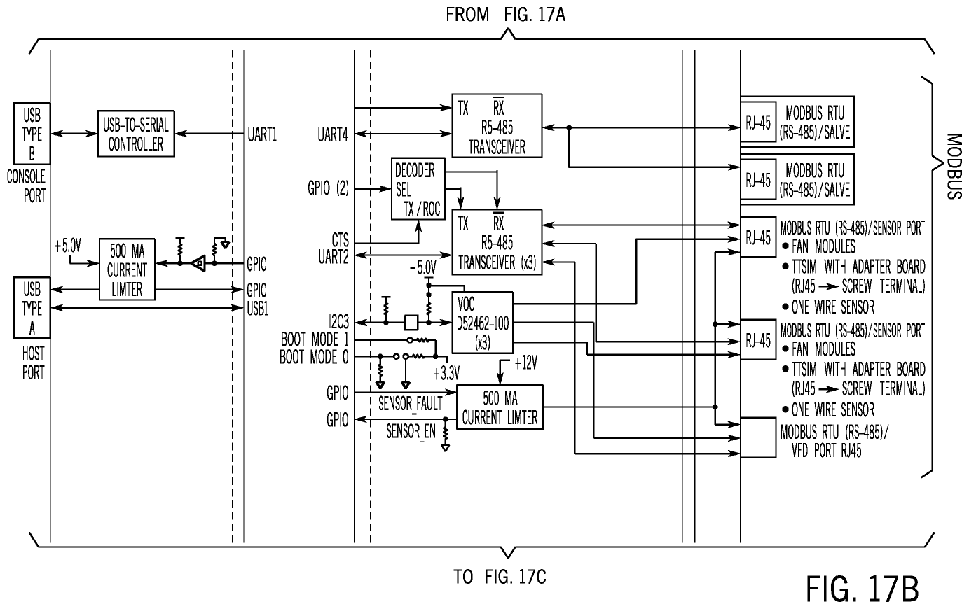

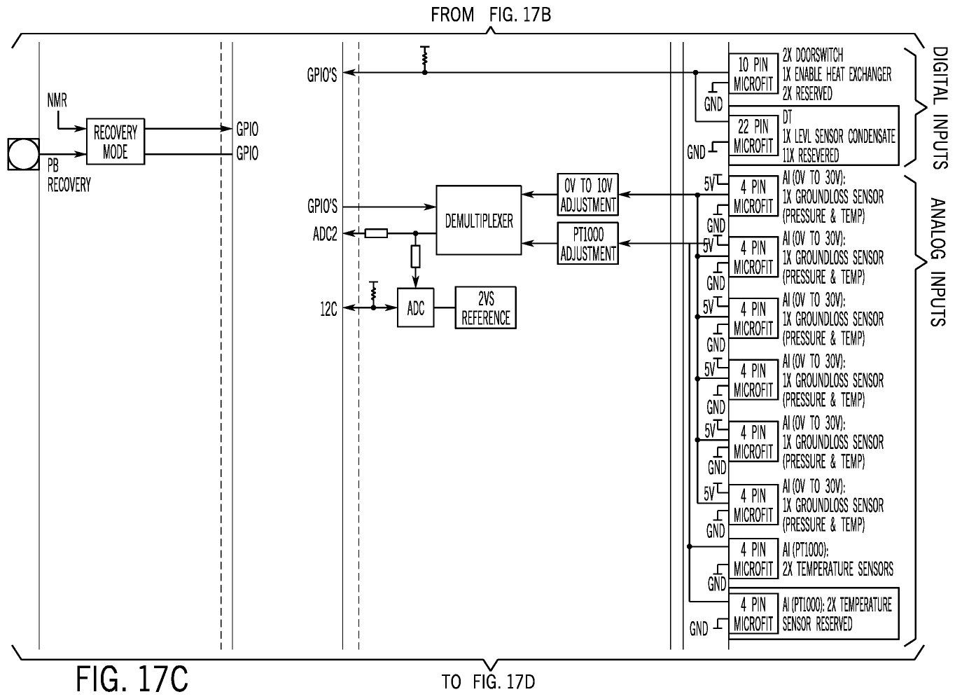

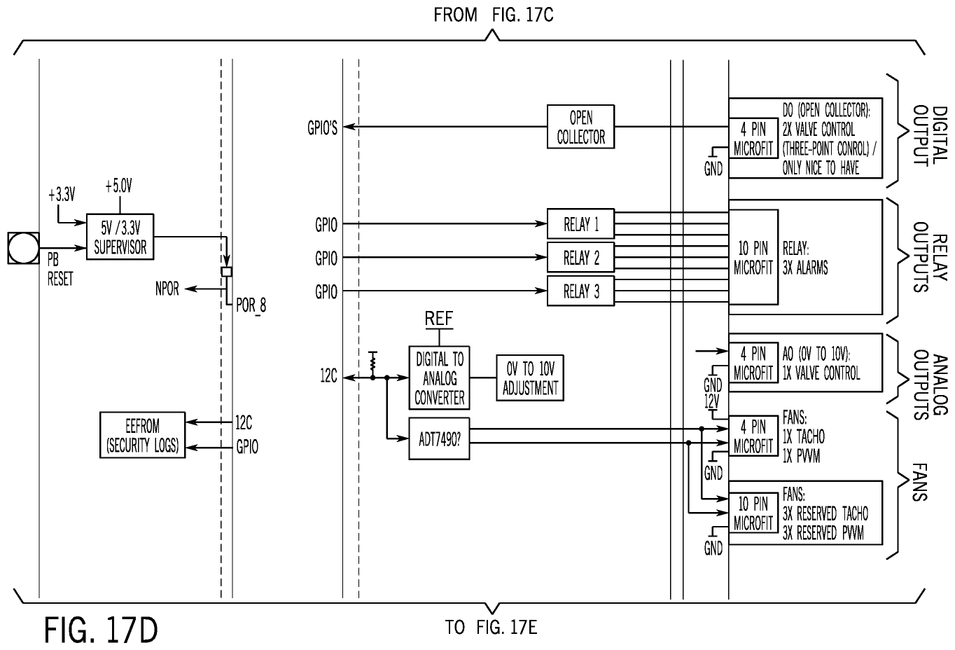

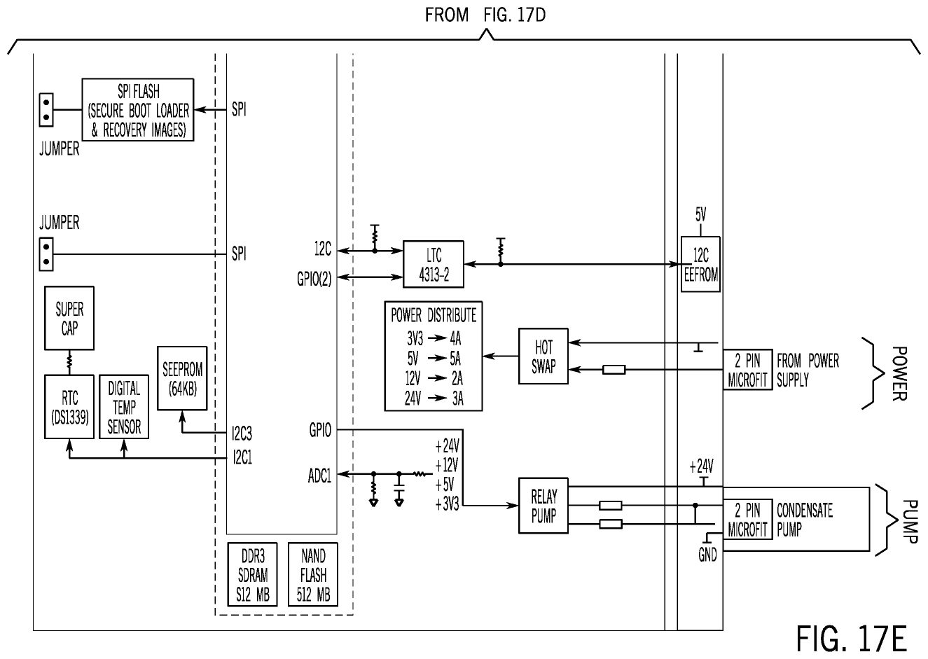

FIGS. 17A, 17B, 17C, 17D and 17E illustrate an embodiment of a controller (e.g., the controller 160 illustrated in FIG. 12), an interface board connected to the controller, the fans (e.g., the fan assemblies 104 shown in FIG. 2), the valve (e.g., the valve 148 shown in FIG. 9). FIGS. 17A, 17B, 17C, 17D and 17E illustrates the electrical schematic for the controller's microprocessor including the various inputs into the microprocessor and the various outputs to the interface board and to the interface board's ports.

The previous description of the disclosed embodiments is provided to enable any person skilled in the art to make or use the disclosed systems. Various modifications to these embodiments will be readily apparent to those skilled in the art, and the generic principles defined herein may be applied to other embodiments without departing from the spirit or scope of the invention. Thus, the invention is not intended to be limited to the embodiments shown herein but is to be accorded the widest scope consistent with the principles and novel features disclosed herein.

1. An air-to-liquid cooling system comprising:
a cabinet defining a front portion and a rear portion, the cabinet including lateral side panels and a front face;
a fluid inlet;
a fluid outlet; and
a heat exchanger within the cabinet, the heat exchanger being in fluid communication with the fluid inlet and the fluid outlet, and being positioned at an oblique angle relative to the lateral side panels;
a plurality of fan assemblies mounted along the front face, each of the plurality of fan assemblies including a fan and blind mate connectors configured to interface with corresponding blind mate connectors within the cabinet;
a hot-swappable control module mounted along the front face, the hot-swappable control module being positioned vertically above the plurality of fan assemblies, and including a controller, the controller being in electronic communication with the plurality of fan assemblies, and having instructions stored thereon to control a speed of the fans of the plurality of fan assemblies.

2. The air-to-liquid cooling system of claim 1, further comprising a plurality of hot-swappable power supply units mounted along the front face.

3. The air-to-liquid cooling system of claim 2, wherein the plurality of hot-swappable power supply units includes three hot-swappable control units.

4. The air to liquid cooling system of claim 2, wherein the plurality of power supply units provide an N+1 redundancy of power supply units for the air-to-liquid cooling system.

5. The air-to-liquid cooling system of claim 2, wherein an axis is defined transverse to the front face, wherein each of the plurality of fan assemblies, the hot-swappable power supply units, and the hot-swappable controller are removable from the cabinet in a direction parallel to the axis.

6. The air-to-liquid cooling system of claim 1, further including a valve positioned downstream of the fluid inlet and upstream of the heat exchanger, the valve movable between a fully open position and a fully closed position, wherein, when the valve is in a fully-closed position, a fluid connection between the heat exchanger and the fluid inlet is interrupted.

7. The air-to-liquid cooling system of claim 6, wherein the valve is in communication with the controller, and wherein the controller is configured to provide a signal to the valve to control a position of the valve.

8. The air-to-liquid cooling system of claim 7, wherein, when the valve is in the fully closed position, the fluid inlet is in direct fluid communication with the fluid outlet.

9. The air-to-liquid cooling system of claim 8, wherein, when a communication between the controller and the plurality of fan assemblies is interrupted, the fans of the fan assemblies continue to rotate at a default speed.

10. The air-to-liquid cooling system of claim 1, wherein vents are defined in the lateral side panels.

11. The air-to-liquid cooling system of claim 1, further comprising a plurality of electrical inlets, wherein the fluid inlet, the fluid outlet, and the plurality of electrical inlets are provided in the rear portion of the cabinet.

12. The air-to-liquid cooling system of claim 1, wherein the cabinet defines a width of about 600 mm.

13. The air-to-liquid cooling system of claim 1, wherein the hot-swappable control module is one of a plurality of hot-swappable control modules, each hot-swappable control module of the plurality of hot-swappable control modules being mounted along the front face.

14. An air-to-liquid cooling system comprising:
a cabinet defining a front portion and a rear portion, the cabinet including lateral side panels and a front face;
a fluid inlet;
a fluid outlet;
a fluid flow path defined between the fluid inlet and the fluid outlet; and
a heat exchanger within the cabinet between the front portion and the rear portion, and being positioned at an oblique angle relative to the lateral side panels;
a bypass valve configured to move between a fully open position and a fully closed position, wherein, in the fully open position the heat exchanger is positioned fluidly along the fluid flow path, and wherein, in the fully closed position, the heat exchanger is not positioned fluidly along the fluid flow path;
a hot-swappable control module mounted within the front portion, the hot-swappable control module including blind mate connectors and a controller, the controller being in electronic communication with the bypass valve, and having instructions stored thereon to control a position of the bypass valve.

15. The air-to-liquid cooling system of claim 14, wherein both the fluid inlet and the fluid outlet comprise a quick-disconnect fitting.

16. The air-to-liquid cooling system of claim 14, further comprising:
a plurality of power supply units mounted at the front portion; and
a plurality of fan assemblies mounted at the front portion.

17. The air-to-liquid cooling system of claim 16, wherein each of the plurality of power supply units and the plurality of fan assemblies include blind mate connections.

18. The air-to-liquid cooling system of claim 16, wherein an axis extends through the front portion and the rear portion, and wherein each of the hot-swappable control module, the plurality of power supply units, and the fan assemblies are configured to be inserted into the front portion in a direction parallel the axis.

19. The air-to-liquid cooling system of claim 16, wherein each of the hot-swappable control module, the plurality of power supply units, and the fan assemblies are configured for toolless removal from the cabinet.

20. A method of providing a cooling system within a data center including:
providing a cabinet defining a front portion and a rear portion, the cabinet having installed therein a heat exchanger, a fluid inlet, and a fluid outlet;
inserting, in a first direction, a hot-swappable fan assembly into the front portion, the hot-swappable fan assembly including a fan;
inserting in the first direction, a hot-swappable control module into the front portion, the hot-swappable control module including a controller have instructions thereon for implementing a fan speed PID control for controlling a speed of the fan;
inserting, in the first direction, a power supply unit into the front portion;
providing, at the fluid inlet, a fluid coolant;
sensing, at a first sensor, a parameter of the fluid coolant;
providing the parameter to the controller; and
based on the parameter, generating, at the controller, a speed signal for the fan of the hot-swappable fan assembly the speed signal being generated based on the fan speed PID control.
